(19) United States
(12) Patent Application Publication
(10) Pub. No.: US 2026/0304897 A1
(43) Pub. Date: Oct. 1, 2026

(54) NITRIDE SEMICONDUCTOR DEVICE

(71) Applicant: Panasonic Holdings Corporation, Osaka (JP)

(72) Inventors: DAISUKE SHIBATA, Kyoto (JP); SATOSHI TAMURA, Osaka (JP)

(21) Appl. No.: 19/534,537

(22) Filed: Feb. 9, 2026

(30) Foreign Application Priority Data
Mar. 13, 2025 (JP) 2025-040553

(51) Int. Cl. H10D 64/27; H10D 30/47; H10D 62/85; H10D 64/23

(52) U.S. Cl. CPC H10D 64/411; H10D 30/4755; H10D 62/8503; H10D 64/257

(57) ABSTRACT

A nitride semiconductor device includes a substrate, a first nitride semiconductor layer of a first conductivity type disposed above the substrate, a second nitride semiconductor layer of a second conductivity type disposed above the first nitride semiconductor layer, the second conductivity type being a polarity opposite to the first conductivity type, and an electron transit layer and an electron supply layer disposed in order from the substrate side, and covering an inner surface of a first opening penetrating the second nitride semiconductor layer and reaching the first nitride semiconductor layer and above the second nitride semiconductor layer. A thickness of the electron supply layer at a first position is thicker than a thickness of the electron supply layer at a second position. The second position is a position closer to the first opening than the first position is in plan view of the substrate.

### BACKGROUND

### 1. Technical Field

The present disclosure relates to a nitride semiconductor device.

### 2. Description of the Related Art

Patent Literature (PTL) 1 discloses a nitride semiconductor device including a 2-dimensional electron gas (2DEG) as a channel. In the nitride semiconductor device disclosed in Patent Literature 1, a p-type semiconductor layer is provided immediately below the gate electrode. The potential of the conduction band edge of the channel portion is raised by the p-type semiconductor layer, the threshold value can be increased, and normally-off of the transistor can be realized.

PTL 1: Japanese Patent No. 6511645

### SUMMARY

A nitride semiconductor device according to an aspect of the present disclosure includes: a substrate; a first nitride semiconductor layer of a first conductivity type disposed above the substrate; a second nitride semiconductor layer of a second conductivity type disposed above the first nitride semiconductor layer, the second conductivity type being a polarity opposite to the first conductivity type; and an electron transit layer and an electron supply layer disposed in order from the substrate side, and covering an inner surface of a first opening penetrating the second nitride semiconductor layer and reaching the first nitride semiconductor layer and above the second nitride semiconductor layer, in which a thickness of the electron supply layer at a first position is thicker than a thickness of the electron supply layer at a second position, and the second position is a position closer to the first opening than the first position is in plan view of the substrate.

### BRIEF DESCRIPTION OF THE DRAWINGS

FIG. 1 is a cross-sectional view of a nitride semiconductor device according to a first exemplary embodiment;

FIG. 2 is a cross-sectional view of a nitride semiconductor device according to a second exemplary embodiment;

FIG. 3 is a cross-sectional view of a nitride semiconductor device according to a third exemplary embodiment;

FIG. 4 is a cross-sectional view of a nitride semiconductor device according to a fourth exemplary embodiment;

FIG. 5 is a cross-sectional view of a nitride semiconductor device according to a fifth exemplary embodiment;

FIG. 6 is a cross-sectional view of a nitride semiconductor device according to a sixth exemplary embodiment; and

FIG. 7 is a cross-sectional view of a nitride semiconductor device according to a seventh exemplary embodiment.

### DETAILED DESCRIPTIONS

The conventional nitride semiconductor device has a problem that it is difficult to achieve both reduction in on-resistance and improvement in off-characteristics.

Therefore, the present disclosure provides a nitride semiconductor device capable of achieving both reduction in on-resistance and improvement in off-characteristics.

### SUMMARY OF PRESENT DISCLOSURE

A nitride semiconductor device according to a first aspect of the present disclosure includes: a substrate; a first nitride semiconductor layer of a first conductivity type disposed above the substrate; a second nitride semiconductor layer of a second conductivity type disposed above the first nitride semiconductor layer, the second conductivity type being a polarity opposite to the first conductivity type; and an electron transit layer and an electron supply layer disposed in order from the substrate side, and covering an inner surface of a first opening penetrating the second nitride semiconductor layer and reaching the first nitride semiconductor layer and above the second nitride semiconductor layer, in which a thickness of the electron supply layer at a first position is larger than a thickness of the electron supply layer at a second position, and the second position is a position closer to the first opening than the first position is in plan view of the substrate.

As a result, the electron supply layer is thin at the second position on the first opening side where electric field concentration is likely to occur, so that the carrier concentration of the 2DEG is reduced. Since the depletion layer easily spreads at the time of OFF, electric field concentration can be alleviated, and OFF characteristics can be improved. Since the electron supply layer is thick at the first position away from the first opening, the carrier concentration of the 2DEG increases. Since the channel resistance or the contact resistance with the electrode can be reduced, the on-resistance can be reduced. As described above, it is possible to achieve both reduction in the on-resistance and improvement in the off-characteristics.

A nitride semiconductor device according to a second aspect of the present disclosure is the nitride semiconductor device according to the first aspect, in which a thickness of the electron supply layer gradually decreases from the first position toward the second position.

As a result, since the change in the upper surface of the electron supply layer can be made gentle, the coverage of the layer formed on the electron supply layer can be improved. Therefore, the quality and reliability of the nitride semiconductor device can be improved.

A nitride semiconductor device according to a third aspect of the present disclosure is the nitride semiconductor device according to the second aspect, in which the electron supply layer is disposed with a recess between the first position and the second position at a position overlapping the second nitride semiconductor layer in plan view of the substrate.

As a result, the threshold of the transistor can be adjusted by the depth of the recess. For example, normally-off of the transistor can be easily realized. In addition, the portion of the electron supply layer on the first position side with respect to the recess can be thickened. Since the carrier concentration of 2DEG increases in the vicinity of the thickened portion, the on-resistance can be reduced.

A nitride semiconductor device according to a fourth aspect of the present disclosure is the nitride semiconductor device according to the first aspect, in which
the thickness of the electron supply layer is constant in each of a first range including the first position and a second range including the second position, and
the second range is a range closer to the first opening than the first range is in plan view of the substrate.

As a result, since the thickness of the electron supply layer can be changed stepwise, it is possible to secure a large region in which the carrier concentration is high and a large region in which the carrier concentration is low. Therefore, it is possible to effectively achieve both the reduction in the on-resistance and the improvement in the off-characteristics.

A nitride semiconductor device according to a fifth aspect of the present disclosure is the nitride semiconductor device according to the fourth aspect, in which the electron supply layer is disposed with a recess inside the second range at a position overlapping the second nitride semiconductor layer in plan view of the substrate.

As a result, the threshold of the transistor can be adjusted by the depth of the recess. For example, normally-off of the transistor can be easily realized. In addition, the first range of the electron supply layer can be thickened. Since the carrier concentration of 2DEG increases in the vicinity of the thickened portion, the on-resistance can be reduced.

A nitride semiconductor device according to a sixth aspect of the present disclosure is the nitride semiconductor device according to any one of the first to fifth aspects, in which a thickness of the electron supply layer at a third position is smaller than the thickness of the electron supply layer at the second position, and the third position is a position overlapping a bottom surface of the first opening in plan view of the substrate.

As a result, since the carrier concentration of the 2DEG in the vicinity of the bottom surface of the first opening can be reduced, the off-characteristics can be further improved.

A nitride semiconductor device according to a seventh aspect of the present disclosure is the nitride semiconductor device according to any one of the first to sixth aspects, and includes a gate electrode disposed above the electron supply layer, a source electrode disposed above the substrate, and a drain electrode disposed below the substrate.

As a result, it is possible to realize a vertical transistor having a high withstand voltage and a large current.

A nitride semiconductor device according to an eighth aspect of the present disclosure is the nitride semiconductor device according to the seventh aspect, in which the gate electrode is disposed at a position overlapping the first opening in plan view of the substrate.

As a result, it is possible to control on and off of the transistor in a portion along the inner surface of the first opening.

A nitride semiconductor device according to a ninth aspect of the present disclosure is the nitride semiconductor device according to the eighth aspect, further including a third nitride semiconductor layer of the second conductivity type disposed between the gate electrode and the electron supply layer, in which the second position overlaps the third nitride semiconductor layer in plan view of the substrate, and the first position is a position located between the third nitride semiconductor layer and the source electrode in plan view of the substrate or overlapping an end portion of the third nitride semiconductor layer on the source electrode side.

As a result, the potential of the conduction band edge of the channel can be increased by the p-type third nitride semiconductor layer, and the threshold of the transistor can be increased. Therefore, normally-off of the transistor can be easily realized.

A nitride semiconductor device according to a tenth aspect of the present disclosure is the nitride semiconductor device according to the seventh aspect, and includes a shielding electrode disposed at a position overlapping the first opening in plan view of the substrate and electrically connected to the source electrode, in which the gate electrode is disposed at a position overlapping the second nitride semiconductor layer without overlapping the first opening in plan view of the substrate.

As a result, since the shielding electrode can terminate the line of electric force extending from the drain electrode, the parasitic capacitance between the gate and the drain can be reduced, and the switching speed can be increased.

A nitride semiconductor device according to an eleventh aspect of the present disclosure is the nitride semiconductor device according to the tenth aspect, the nitride semiconductor device including: the third nitride semiconductor layer of the second conductivity type disposed between the gate electrode and the electron supply layer; and the fourth nitride semiconductor layer of the second conductivity type disposed between the shielding electrode and the electron supply layer, in which the second position overlaps the fourth nitride semiconductor layer in plan view of the substrate, and the first position is a position located between the third nitride semiconductor layer and the source electrode in plan view of the substrate or overlapping an end portion of the third nitride semiconductor layer on the source electrode side.

As a result, the potential of the conduction band edge of the channel can be increased by the p-type third nitride semiconductor layer, and the threshold of the transistor can be increased. Therefore, normally-off of the transistor can be easily realized.

Hereinafter, exemplary embodiments will be specifically described with reference to the drawings.

Note that each of the exemplary embodiments described below illustrates a comprehensive or specific example. Numerical values, shapes, materials, components, arrangement positions and connection modes of the components, steps, order of the steps, and the like shown in the following exemplary embodiments are merely examples, and are not intended to limit the present disclosure. Further, among the components in the following exemplary embodiments, components not recited in the independent claims are described as arbitrary components.

Each of the drawings is a schematic diagram, and is not necessarily strictly illustrated. Therefore, for example, scales and the like do not necessarily coincide in the respective drawings. In each drawing, substantially the same components are denoted by the same reference numerals, and redundant description will be omitted or simplified.

In addition, in the present specification, the term indicating the relationship between elements such as parallel and orthogonal, the term indicating the shape of an element such as a rectangle, and the numerical range are not expressions representing only a strict meaning, but are expressions meaning to include a substantially equivalent range, for example, a difference of about several%.

In addition, in the present specification, the “thickness direction” of the substrate refers to a direction perpendicular to the main surface of the substrate. The thickness direction is the same as the stacking direction of the semiconductor layers, and is also referred to as “vertical direction”. In addition, a direction parallel to the main surface of the substrate may be referred to as a “lateral direction”. The “vertical” semiconductor device means a device in which a main path of a current such as a drain current or a forward current is vertical, that is, a device in which a main current passes through a substrate in the vertical direction. A “lateral” semiconductor device means a device in which the main path of current, such as a drain current or a forward current, is lateral, that is, a device in which a main current does not pass through the substrate.

In addition, a side on which a heterostructure that generates 2DEG is provided with respect to the substrate is regarded as “above” or “upper side”, and the opposite side is regarded as “below” or “lower side”. In the present description, the terms “above” and “below” do not refer to an upper direction (vertically upward) and a lower direction (vertically downward) in absolute space recognition, but are used as terms defined by a relative location relationship based on a stacking order in a stacking configuration. Also, the terms “above” and “below” apply not only when two components are spaced apart from each other and there is another component between the two components, but also when the two components are disposed in close contact with each other and the two components are in contact.

In addition, in the present specification, unless otherwise specified, “plan view” refers to when viewed from a direction perpendicular to the main surface of the substrate of the semiconductor device, that is, when the main surface of the substrate is viewed from the front.

In addition, in the present specification, “A and B overlap in plan view” means that at least a part of A and at least a part of B overlap. That is, a case where only a part of A and only a part of B overlap, a case where all of A overlap B, a case where all of B overlap A, and a case where A and B completely overlap each other are included.

In addition, the n-type and the p-type indicate the conductivity types of the semiconductor, and are conductivity types having opposite polarities to each other. The n-type is an example of a first conductivity type, and the p-type is an example of a second conductivity type. An n⁺-type indicates a state in which an n-type dopant is added to a semiconductor at a high concentration, the state being so-called heavy doping. In addition, an n⁻-type indicates a state in which an n-type dopant is added to a semiconductor at a low concentration, the state being so-called light doping. Both the n⁺-type and the n⁻-type are examples of the n-type, and the n⁺-type and the n⁻-type may be described as the n-type without being distinguished from each other. The same applies to the p-type, the p⁺-type, and the p⁻-type.

In addition, in the present specification, the “main component” means a component having the highest content ratio among all the components constituting the member. For example, a component having a content ratio of 50% or more is a main component. The component is a material, an element, a compound, or the like.

In addition, in the present specification, AlGaN represents ternary mixed crystal AlₓGa₁₋ₓN (0<x<1). Hereinafter, the multicomponent mixed crystal is abbreviated as an arrangement of constituent element symbols, for example, AlInN, GaInN, and the like. For example, AlₓGa_{1-x-y}In_{y}N (0<x<1, 0<y<1, and 0<x+y<1), which is an example of a nitride semiconductor, is abbreviated as AlGaInN. x, 1-x-y, and y represent composition ratios of Al, Ga, and In, respectively.

In addition, in the present specification, ordinal numbers such as “first” and “second” do not mean the number or order of constituent elements unless otherwise specified, and are used for the purpose of avoiding confusion and distinguishing the same kind of constituent elements.

### FIRST EXEMPLARY EMBODIMENT

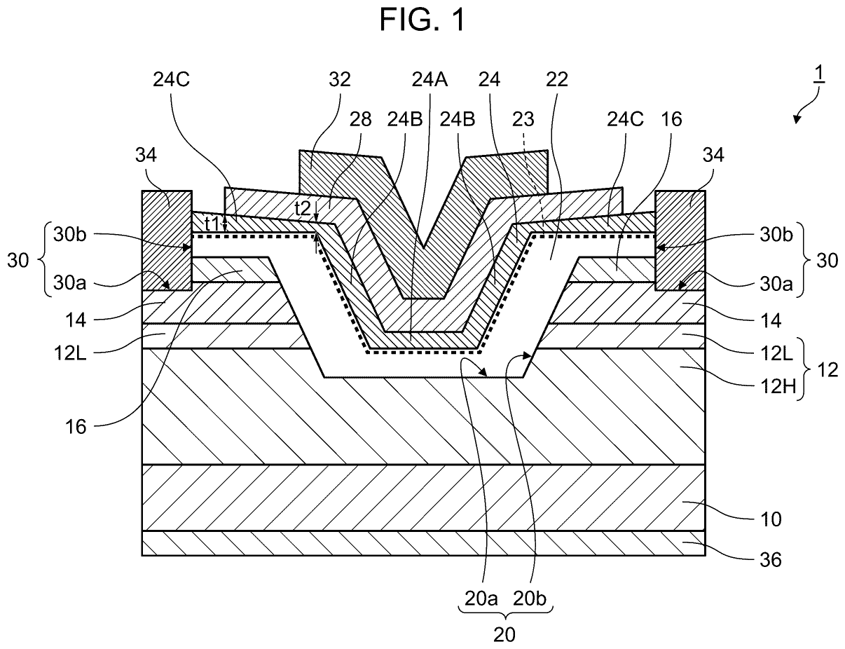

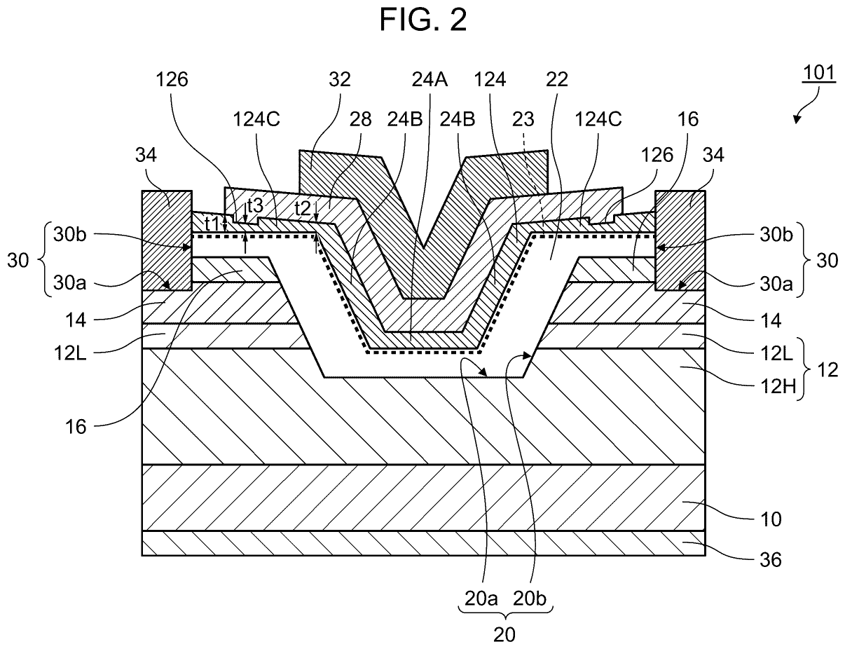

FIG. 1 is a cross-sectional view of nitride semiconductor device 1 according to the present exemplary embodiment. In FIG. 1, each component such as a semiconductor layer, an insulating layer, and an electrode included in nitride semiconductor device 1 is hatched to represent a cross section. Note that hatching of hatched line representing a cross section is omitted for electron transit layer 22. The same applies to other cross-sectional views after FIG. 2.

Nitride semiconductor device 1 illustrated in FIG. 1 is a normally-off type vertical field effect transistor (FET). In nitride semiconductor device 1, for example, source electrode 34 is grounded, and a positive potential is applied to drain electrode 36. The potential applied to drain electrode 36 is, for example, between 100 V and 1200 V (inclusive), but is not limited thereto. In nitride semiconductor device 1, a modulation operation according to the potential applied to gate electrode 32 is performed. For example, when 0 V or a negative potential (for example, −5 V) is applied to gate electrode 32, no current flows between drain electrode 36 and source electrode 34. That is, nitride semiconductor device 1 goes into a non-conductive state (OFF). When a positive potential (for example, +5 V) is applied to gate electrode 32, a current flows from drain electrode 36 to source electrode 34. That is, nitride semiconductor device 1 is brought into a conductive state (ON). The current flowing from drain electrode 36 to source electrode 34 in the ON state is referred to as a drain current. The drain current flows through substrate 10 in the thickness direction thereof (that is, in the vertical direction).

As illustrated in FIG. 1, nitride semiconductor device 1 includes substrate 10, drift layer 12, block layer 14, base layer 16, electron transit layer 22, electron supply layer 24, threshold adjustment layer 28, gate electrode 32, source electrode 34, and drain electrode 36. Nitride semiconductor device 1 is provided with first opening 20 and second opening 30. Second opening 30 and source electrode 34 are provided on both left and right sides of first opening 20 in the cross-sectional view illustrated in FIG. 1.

Nitride semiconductor device 1 is a device in which a semiconductor layer including a channel contains a nitride semiconductor as a main component. Specifically, each of drift layer 12, block layer 14, base layer 16, electron transit layer 22, electron supply layer 24, and threshold adjustment layer 28 contains a nitride semiconductor as a main component.

Hereinafter, details of each component included in nitride semiconductor device 1 will be described.

Substrate 10 is, for example, a substrate containing n⁺-type GaN having a thickness of 300 μm and a carrier concentration of 5×10¹⁸ cm⁻³ as a main component.

Note that substrate 10 may not be a nitride semiconductor substrate. For example, substrate 10 may be a Si substrate, a SiC substrate, a ZnO substrate, or the like.

Drift layer 12 is an example of an n-type first nitride semiconductor layer, and is provided above substrate 10. In the present exemplary embodiment, drift layer 12 includes high-concentration layer 12H and low-concentration layer 12L. Each of high-concentration layer 12H and low-concentration layer 12L is a nitride semiconductor layer, and is, for example, a film containing n-type GaN as a main component. High-concentration layer 12H is a layer having a higher donor concentration than low-concentration layer 12L. The donor concentration of low-concentration layer 12L is, for example, between 1×10¹⁵ cm⁻³ and 1×10¹⁷ cm⁻³ (inclusive), and is 1×10¹⁶ cm⁻³ as an example. The donor concentration of high-concentration layer 12H is, for example, between 3×10¹⁵ cm⁻³ and 1×10¹⁷ cm⁻³ (inclusive), and is 1.5×10¹⁶ cm⁻³ as an example.

High-concentration layer 12H is provided in contact with, for example, the upper surface (main surface) of substrate 10. Low-concentration layer 12L is provided between high-concentration layer 12H and block layer 14. For example, low-concentration layer 12L is provided between the upper surface of high-concentration layer 12H and the lower surface of block layer 14 in contact with each of them. The thickness of high-concentration layer 12H is, for example, between 2 μm and 20 μm (inclusive). The thickness of low-concentration layer 12L is, for example, between 0.05 μm and 2 μm (inclusive).

Since low-concentration layer 12L is provided, the depletion layer easily spreads from p-type block layer 14. Therefore, the withstand voltage of nitride semiconductor device 1 can be increased. In addition, since high-concentration layer 12H is provided, the resistance of the path through which the drain current passes can be reduced, and the on-resistance can be reduced.

Drift layer 12 may have a stacked structure of three or more nitride semiconductor layers having different donor concentrations. In this case, the donor concentration of each layer is configured to decrease as it goes upward. Alternatively, drift layer 12 may have a graded structure in which the donor concentration gradually decreases as it goes upward. Drift layer 12 may be a film containing, as a main component, n⁻-type GaN having a uniform donor concentration. Drift layer 12 may contain carbon (C), and the carbon concentration of drift layer 12 may be, for example, between 1×10¹⁵ cm⁻³ and 5×10¹⁶ cm⁻³ (inclusive).

Block layer 14 is an example of a p-type second nitride semiconductor layer, and is provided above drift layer 12. Block layer 14 is, for example, a film containing, as a main component, p-type GaN having a thickness of 400 nm and a carrier concentration of 1×10¹⁷ cm⁻³. Block layer 14 is provided in contact with the upper surface of drift layer 12.

Base layer 16 is an example of a nitride semiconductor layer, and is provided above block layer 14. Base layer 16 is a high-resistance layer having higher resistance than block layer 14. Base layer 16 is, for example, a layer containing i-type GaN having a thickness of 200 nm as a main component. Base layer 16 is provided in contact with the upper surface of block layer 14.

Base layer 16 is an undoped nitride semiconductor layer, but may be an insulating layer or a semi-insulating layer. Base layer 16 may be doped with carbon. For example, the carbon concentration of base layer 16 is higher than the carbon concentration of block layer 14. For example, the carbon concentration of base layer 16 is 3×10¹⁷ cm⁻³ or more, but may be 1×10¹⁸ cm⁻³ or more. At this time, each concentration of silicon (Si) or oxygen (O) to be the n-type impurity is lower than the carbon concentration. For example, the silicon concentration or the oxygen concentration of base layer 16 is 5×10¹⁶ cm⁻³ or less, but may be 2×10¹⁶ cm⁻³ or less. As the type of ions to be injected into base layer 16, ion species other than the above ion species can provide the same effect as long as the ion species can increase the resistance of the semiconductor layer. Note that base layer 16 may not be provided.

Block layer 14 and base layer 16 are provided with first opening 20. First opening 20 penetrates base layer 16 and block layer 14 and reaches drift layer 12. In the present exemplary embodiment, first opening 20 penetrates low-concentration layer 12L of drift layer 12 and reaches high-concentration layer 12H. First opening 20 may be referred to as a gate opening or a vertical conduction opening. Bottom surface 20a of first opening 20 is a part of high-concentration layer 12H. As illustrated in FIG. 1, bottom surface 20a is located at a lower side than the lower surface of low-concentration layer 12L. Bottom surface 20a is, for example, parallel to the main surface of substrate 10. When nitride semiconductor device 1 is on, a drain current flows between drain electrode 36 and source electrode 34 through bottom surface 20a of first opening 20.

In the present exemplary embodiment, first opening 20 is formed such that the opening area increases as it goes away from substrate 10. Specifically, side surface 20b of first opening 20 is inclined obliquely. As illustrated in FIG. 1, the cross-sectional view shape of first opening 20 is an inverted trapezoid, more specifically, an inverted isosceles trapezoid.

The inclination angle of side surface 20b with respect to bottom surface 20a is, for example, between 20° and 80° (inclusive), but may be between 30° and 45° (inclusive). Since side surface 20b approaches the c-plane as the inclination angle decreases, the film quality of electron transit layer 22 and the like formed along side surface 20b by crystal regrowth can be improved. On the other hand, as the inclination angle increases, first opening 20 is suppressed from becoming too large, and miniaturization of nitride semiconductor device 1 is realized. Side surface 20b may be perpendicular to bottom surface 20a.

Electron transit layer 22 is provided above substrate 10. Specifically, electron transit layer 22 is an example of a first regrowth layer, and is provided so as to cover the inner surface of first opening 20 and above block layer 14. For example, a part of electron transit layer 22 is provided along bottom surface 20a and side surface 20b of first opening 20, and the other part of electron transit layer 22 is provided on the upper surface of base layer 16. The thickness of electron transit layer 22 is, for example, between 50 nm and 300 nm (inclusive). Electron transit layer 22 is, for example, a film containing undoped GaN having a thickness of 150 nm as a main component. Note that the thickness of electron transit layer 22 is regarded as the thickness on the outer side of first opening 20, specifically, on a flat portion that is a portion overlapping the upper surface of block layer 14 in plan view of substrate 10. Further, electron transit layer 22 is assumed to be undoped, but may be partially made into an n-type by Si doping or the like.

Electron transit layer 22 is in contact with drift layer 12 on bottom surface 20a and side surface 20b of first opening 20. Electron transit layer 22 is in contact with block layer 14 on side surface 20b of first opening 20. Specifically, electron transit layer 22 is in contact with the upper surface of base layer 16.

Electron transit layer 22 has a channel. Specifically, 2DEG 23 serving as a channel is generated in the vicinity of the interface between electron transit layer 22 and electron supply layer 24. 2DEG 23 is bent along the interface between electron transit layer 22 and electron supply layer 24, that is, along the inner surface of first opening 20.

Although not illustrated in FIG. 1, an AlN layer having a thickness of about 1 nm is provided as a second regrowth layer between electron transit layer 22 and electron supply layer 24. As a result, alloy scattering is suppressed, channel mobility is improved, and on-resistance can be reduced. Note that the AlN layer is not necessarily required.

Electron supply layer 24 is provided above electron transit layer 22. That is, electron transit layer 22 and electron supply layer 24 are provided in this order from substrate 10 side. Specifically, electron supply layer 24 is an example of a third regrowth layer, and is provided so as to cover the inner surface of first opening 20 and above block layer 14. Specifically, electron supply layer 24 is provided along the upper surface of electron transit layer 22 so as to overlap bottom surface 20a and side surface 20b of first opening 20 and the upper surface of base layer 16 in plan view of substrate 10.

Electron supply layer 24 has a band gap larger than that of electron transit layer 22. For example, electron supply layer 24 is a film containing undoped AlGaN as a main component. Therefore, an AlGaN/GaN hetero interface is formed between electron supply layer 24 and electron transit layer 22. Electron supply layer 24 supplies electrons to a channel (2DEG 23) formed in electron transit layer 22.

The thickness of electron supply layer 24 varies depending on the site. Specifically, thickness t1 of electron supply layer 24 at the first position is larger than thickness t2 of electron supply layer 24 at the second position. Here, the second position is a position closer to first opening 20 than the first position is in plan view. In the present exemplary embodiment, the first position does not overlap first opening 20 in plan view, and the second position overlaps first opening 20 in plan view. In the present specification, the thickness of electron supply layer 24 is represented by a distance between the lower surface and the upper surface of electron supply layer 24 on one straight line orthogonal to the main surface of substrate 10.

Electron supply layer 24 includes bottom portion 24A, inclined portion 24B, and upper stage portion 24C. Inclined portion 24B and upper stage portion 24C are provided on both sides of bottom portion 24A.

Bottom portion 24A is a portion overlapping bottom surface 20a of first opening 20 in plan view of substrate 10, and is a portion having a substantially uniform thickness. The upper surface and the lower surface of bottom portion 24A are parallel to each other and parallel to the main surface of substrate 10. When the size of bottom surface 20a of first opening 20 is small, the lower portions of two inclined portions 24B are connected to each other, and bottom portion 24A may not be provided.

Inclined portion 24B is a portion inclined along side surface 20b of first opening 20. Specifically, both the lower surface and the upper surface of inclined portion 24B are inclined so as to be substantially parallel to side surface 20b. Note that the lower surface and the upper surface of inclined portion 24B may not be parallel to each other, and for example, inclined portion 24B may be thicker in the lower portion of inclined portion 24B. The upper surface of inclined portion 24B may not be a flat inclined surface, and may be a surface curved in a concave shape or a convex shape.

Upper stage portion 24C is a portion extending from the upper portion of inclined portion 24B to source electrode 34. Specifically, upper stage portion 24C can be regarded as a portion located outside first opening 20, that is, above the upper surface of block layer 14, and the lower surface of upper stage portion 24C is parallel to substrate 10. A part of upper stage portion 24C overlaps block layer 14 in plan view of substrate 10.

In the present exemplary embodiment, the lower surface of upper stage portion 24C is parallel to the main surface of substrate 10, whereas the upper surface of upper stage portion 24C is inclined with respect to the main surface of substrate 10. Specifically, the upper surface of upper stage portion 24C is inclined in a direction approaching substrate 10 from source electrode 34 toward first opening 20.

Since the upper surface of upper stage portion 24C is inclined, the thickness of upper stage portion 24C gradually decreases from the first position toward the second position. Thickness t1 at the first position is 23 nm, whereas thickness t2 at the second position is 20 nm. Thicknesses t1 and t2 are, for example, between 10 nm and 70 nm (inclusive).

Here, the first position is a position overlapping an end portion of threshold adjustment layer 28 on source electrode 34 side in plan view of substrate 10. When threshold adjustment layer 28 is not provided, the first position can be regarded as a position overlapping the end portion of gate electrode 32 on source electrode 34 side. The second position overlaps threshold adjustment layer 28 in plan view of substrate 10. Specifically, the second position can be regarded as a position farthest from source electrode 34 in the flat portion of the upper surface of electron transit layer 22 in the gate length direction, that is, the position of the end portion of upper stage portion 24C of electron supply layer 24.

The gate length direction is a direction in which source electrode 34 and gate electrode 32 are arranged, and corresponds to the left-right direction in the cross-sectional view illustrated in FIG. 1. The cross section illustrated in FIG. 1 is a cross section parallel to the gate length direction and orthogonal to the gate width direction. The gate width direction corresponds to the depth direction in the cross-sectional view.

In addition, in a case where electron supply layer 24 contains AlGaN having an Al composition ratio of 20% as a main component, cracks are likely to occur when the thickness of electron supply layer 24 exceeds 70 nm. For this reason, the film quality of electron supply layer 24 is deteriorated, which may cause leakage, or 2DEG 23 may not be generated at a desired concentration. When the Al composition ratio is lowered, occurrence of cracks can be suppressed, so that the thickness of electron supply layer 24 may be, for example, between 10 nm and 150 nm (inclusive). The Al composition ratio of electron supply layer 24 is not particularly limited, but is, for example, between 10% and 30% (inclusive).

Threshold adjustment layer 28 is an example of a p-type third nitride semiconductor layer, and is provided between gate electrode 32 and electron supply layer 24. Threshold adjustment layer 28 overlaps first opening 20 in plan view of substrate 10, and is electrically connected to gate electrode 32. Specifically, threshold adjustment layer 28 contacts and covers the upper surfaces of bottom portion 24A, inclined portion 24B, and upper stage portion 24C of electron supply layer 24.

Threshold adjustment layer 28 is, for example, a film containing p-type GaN having a thickness of 50 nm and a carrier concentration of 5×10¹⁷ cm⁻³ as a main component. The thickness of threshold adjustment layer 28 is, for example, between 100 nm and 500 nm (inclusive). The thickness and carrier concentration of threshold adjustment layer 28 are merely examples, and can be changed as appropriate. For example, threshold adjustment layer 28 may be a film containing p-type AlGaN as a main component.

Second opening 30 penetrates electron supply layer 24, electron transit layer 22, and base layer 16 and reaches block layer 14. Second opening 30 may be referred to as a source opening. Second opening 30 is provided at a position away from both gate electrode 32 and threshold adjustment layer 28 in plan view of substrate 10. Since second opening 30 penetrates electron transit layer 22, 2DEG 23 is exposed to side surface 30b of second opening 30.

Bottom surface 30a of second opening 30 is a part of block layer 14. Bottom surface 30a is, for example, parallel to the main surface of substrate 10. In the example illustrated in FIG. 1, bottom surface 30a is located at a lower side than the lower surface of base layer 16.

In the example illustrated in FIG. 1, side surface 30b of second opening 30 is perpendicular to bottom surface 30a, but the present invention is not limited thereto. Side surface 30b may be inclined obliquely with respect to bottom surface 30a. That is, second opening 30 may be formed such that the opening area increases as the distance from substrate 10 increases. At this time, an inclination angle of side surface 30b with respect to bottom surface 30a is, for example, in a range from 30° to 60° inclusive. Since side surface 30b is inclined obliquely, the contact area between source electrode 34 and the 2DEG 23 increases, so that ohmic connection is easily performed. Note that 2DEG 23 is exposed to side surface 30b of second opening 30, and is connected to source electrode 34 at the exposed portion.

Since second opening 30 is provided, ohmic contact resistance between 2DEG 23 functioning as a channel and source electrode 34 can be reduced. That is, the on-resistance of nitride semiconductor device 1 can be reduced.

Source electrode 34 and block layer 14 are electrically connected to each other at bottom surface 30a of second opening 30. As a result, the same potential as the potential applied to source electrode 34 is supplied to block layer 14. In a case where a reverse voltage is applied to the pn junction formed by block layer 14 and drift layer 12, specifically, in a case where drain electrode 36 has a higher potential than source electrode 34, the depletion layer extends to drift layer 12, so that the breakdown voltage of nitride semiconductor device 1 can be increased.

Gate electrode 32 is provided above electron supply layer 24. Specifically, gate electrode 32 is provided in contact with the upper surface of threshold adjustment layer 28, and is electrically connected to threshold adjustment layer 28. Gate electrode 32 is provided at a position overlapping first opening 20 in plan view of substrate 10. Specifically, gate electrode 32 overlaps bottom surface 20a and side surface 20b of first opening 20 in plan view of substrate 10.

Gate electrode 32 is formed using, for example, a conductive material such as metal. For example, gate electrode 32 may use a material which is ohmic-connected to a p-type nitride semiconductor such as p-type GaN, but is not limited thereto, and may use a material which is Schottky-connected to a p-type nitride semiconductor. For example, Pd, a Ni-based material, WSi, Au, or the like can be used as a material for forming gate electrode 32.

Source electrode 34 is provided above block layer 14. In the present exemplary embodiment, source electrode 34 is electrically connected to block layer 14 through second opening 30. In addition, source electrode 34 is electrically connected to electron transit layer 22 through second opening 30. Specifically, source electrode 34 is provided in contact with bottom surface 30a and side surface 30b of second opening 30. Source electrode 34 is in contact with block layer 14 at bottom surface 30a of second opening 30. Source electrode 34 is in contact with 2DEG 23 on side surface 30b of second opening 30. As a result, the contact resistance between source electrode 34 and 2DEG 23 can be reduced, so that the on-resistance of nitride semiconductor device 1 can be reduced.

Source electrode 34 is formed using a conductive material such as metal. As a material of source electrode 34, for example, a material that is ohmic-connected to an n-type nitride semiconductor such as n-type GaN by heat treatment, such as Ti/Al (stacked structure of Ti layer and Al layer), can be used.

Drain electrode 36 is provided below substrate 10. Specifically, drain electrode 36 is provided in contact with the lower surface of substrate 10.

Drain electrode 36 is formed using a conductive material such as metal. As the material of drain electrode 36, similarly to the material of source electrode 34, for example, a material such as Ti/Al that is ohmic-connected to an n-type nitride semiconductor such as n-type GaN can be used.

In nitride semiconductor device 1 configured as described above, the thickness of electron supply layer 24 gradually decreases from source electrode 34 toward first opening 20. Since electron supply layer 24 is thinner on first opening 20 side where the electric field tends to be concentrated, the carrier concentration of 2DEG 23 is reduced. As a result, since the depletion layer is easily widened at the time of OFF, electric field concentration can be alleviated, and OFF characteristics can be improved.

In addition, since electron supply layer 24 is thicker on source electrode 34 side, the carrier concentration of 2DEG 23 increases. Since the channel resistance or the contact resistance with source electrode 34 can be reduced, the on-resistance can be reduced. As described above, it is possible to achieve both reduction in the on-resistance and improvement in the off-characteristics.

A method for manufacturing nitride semiconductor device 1 is not particularly limited, but for example, the following manufacturing method can be used.

First, a nitride semiconductor is crystal-grown by epitaxial growth on the main surface of substrate 10 to form a plurality of nitride semiconductor films. Specifically, high-concentration layer 12H, low-concentration layer 12L, block layer 14, and base layer 16 of drift layer 12 are formed in this order on the main surface of substrate 10. The epitaxial growth is performed by, for example, metal organic chemical vapor deposition (MOCVD) or the like. In the epitaxial growth, the composition, thickness, conductivity type, impurity concentration, and the like of the nitride semiconductor film can be adjusted by adjusting growth conditions such as a raw material, a growth temperature, a growth time, and a growth rate. The formation of base layer 16 may be omitted.

Thereafter, a part of each of base layer 16, block layer 14, and low-concentration layer 12L is removed to form first opening 20. For example, base layer 16, block layer 14, and low-concentration layer 12L are removed by photolithography, dry etching, or the like. At this time, by removing a part of the surface layer portion of high-concentration layer 12H continuously from the removal of low-concentration layer 12L, bottom surface 20a of first opening 20 is formed below the interface between low-concentration layer 12L and high-concentration layer 12H as illustrated in FIG. 1.

Next, a nitride semiconductor is crystal-grown by second epitaxial growth so as to cover bottom surface 20a and side surface 20b of first opening 20 and above block layer 14 (specifically, the upper surface of base layer 16). Specifically, electron transit layer 22, electron supply layer 24, and threshold adjustment layer 28 are formed in this order. At this time, the crystal growth of electron supply layer 24 is performed, for example, under a condition that the growth in the lateral direction is promoted. As a result, the material for forming upper stage portion 24C of electron supply layer 24 is easily sucked into first opening 20, and a gentle inclination is formed on the upper surface of upper stage portion 24C. Therefore, the thickness of upper stage portion 24C of electron supply layer 24 gradually decreases from the first position toward the second position.

Next, a part of each of threshold adjustment layer 28, electron supply layer 24, electron transit layer 22, and base layer 16 is removed to form second opening 30. For example, each layer is removed by photolithography, dry etching, and the like. At this time, by removing a part of the surface layer portion of block layer 14 continuously from the removal of base layer 16, bottom surface 30a of second opening 30 is formed below the interface between block layer 14 and base layer 16 as illustrated in FIG. 1. Further, by removing a part of threshold adjustment layer 28, threshold adjustment layer 28 is patterned into a predetermined shape. As a result, a portion in the vicinity of second opening 30 in upper stage portion 24C of electron supply layer 24 is exposed without being covered with threshold adjustment layer 28.

Next, gate electrode 32 and source electrode 34 are formed. For example, first, a conductive film is formed using a conductive material ohmic-connected to an n-type nitride semiconductor, and then patterning is performed into a predetermined shape to form source electrode 34. The conductive film is formed by sputtering, vapor deposition, or the like. Patterning of the conductive film is performed by etching, a lift-off method, or the like. Source electrode 34 is formed so as to be in contact with and cover bottom surface 30a and side surface 30b of second opening 30 and not to contact threshold adjustment layer 28. Next, a conductive film is formed using a conductive material ohmic-connected to a p-type nitride semiconductor, and then patterned into a predetermined shape to form gate electrode 32. Formation and patterning of the conductive film are the same as in the case of source electrode 34. Gate electrode 32 is formed on the upper surface of threshold adjustment layer 28 so as not to contact the upper surface of electron supply layer 24 and source electrode 34.

Next, drain electrode 36 is formed on the lower surface of substrate 10. For example, drain electrode 36 is formed by forming a conductive film using a conductive material ohmic-connected to an n-type nitride semiconductor. The conductive film is formed by sputtering, vapor deposition, or the like.

Through the above steps, nitride semiconductor device 1 illustrated in FIG. 1 can be manufactured.

### SECOND EXEMPLARY EMBODIMENT

Then, a second exemplary embodiment will be described.

The second exemplary embodiment is mainly different from the first exemplary embodiment in that a recess is provided in the electron supply layer. Hereinafter, differences from the first exemplary embodiment will be mainly described, and description of common points will be omitted or simplified.

FIG. 2 is a cross-sectional view of nitride semiconductor device 101 according to the present exemplary embodiment. Nitride semiconductor device 101 illustrated in FIG. 2 includes electron supply layer 124 instead of electron supply layer 24 as compared with nitride semiconductor device 1 illustrated in FIG. 1.

Recess 126 is provided in upper stage portion 124C of electron supply layer 124. Upper stage portion 124C has the same configuration as upper stage portion 24C, except that recess 126 is provided. Recess 126 is provided on both left and right sides of first opening 20.

Recess 126 is provided between a first position where the thickness becomes t1 and a second position where the thickness becomes t2 at a position overlapping block layer 14 in plan view of substrate 10. Part or all of recess 126 may overlap side surface 20b of first opening 20 in plan view of substrate 10. Recess 126 is a recess recessed from the upper surface of electron supply layer 124 toward substrate 10. The bottom surface of recess 126 is inclined similarly to the upper surface of upper stage portion 124C of electron supply layer 124. A side surface of recess 126 is perpendicular to the main surface of substrate 10, but may be inclined obliquely.

Threshold adjustment layer 28 is provided so as to cover recess 126. In a portion where recess 126 is provided, the thickness of electron supply layer 124 becomes small. As illustrated in FIG. 2, thickness t3 of a portion of electron supply layer 124 where recess 126 is provided is smaller than both thickness t1 at the first position and thickness t2 at the second position. That is, the relationship of t3<t2<t1 is satisfied.

As thickness t3 decreases, the concentration of 2DEG 23 in the direction immediately below recess 126 decreases. Therefore, the threshold of the transistor can be increased. For example, the threshold can be made higher than 0 V, which facilitates normally-off of the transistor. By adjusting the magnitude of thickness t3, the threshold of the transistor can be determined. For example, thickness t3 is between 10 nm and 60 nm (inclusive), for example, 20 nm.

In addition, a portion of upper stage portion 124C of electron supply layer 124 where recess 126 is not provided can be thickened without affecting the threshold of the transistor. That is, both thickness t1 at the first position and thickness t2 at the second position can be made large. For example, thicknesses t1 and t2 are between 10 nm and 70 nm (inclusive). As an example, thickness t1 is 65 nm and thickness t2 is 60 nm. By thickening the portion where recess 126 is not provided, the concentration of 2DEG 23 increases, so that the on-resistance can be reduced. By providing recess 126 in this manner, it is possible to achieve both the normally-off and the reduction in the on-resistance.

Recess 126 is formed by removing a part of electron supply layer 124 after forming electron supply layer 124 and before forming threshold adjustment layer 28. Electron supply layer 124 is removed by etching.

### THIRD EXEMPLARY EMBODIMENT

Then, a third exemplary embodiment will be described.

The third exemplary embodiment is different from the second exemplary embodiment mainly in that a gate electrode is provided at a position not overlapping the first opening in plan view and a shielding electrode is provided at a position overlapping the first opening. Hereinafter, differences from the second exemplary embodiment will be mainly described, and description of common points will be omitted or simplified.

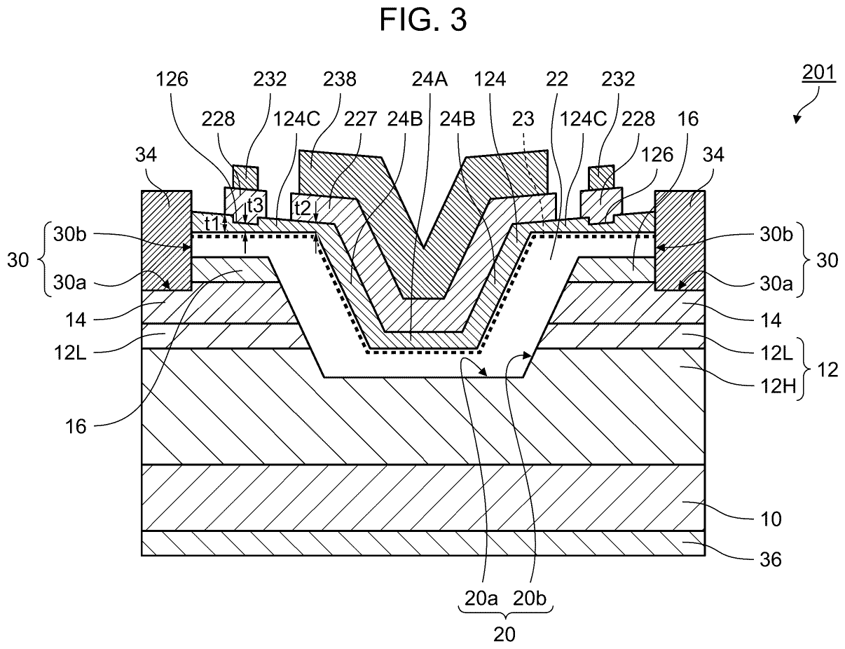

FIG. 3 is a cross-sectional view of nitride semiconductor device 201 according to the present exemplary embodiment. As compared with nitride semiconductor device 101 shown in FIG. 2, nitride semiconductor device 201 shown in FIG. 3 includes shielding layer 227, threshold adjustment layer 228, gate electrode 232, and shielding electrode 238 instead of threshold adjustment layer 28 and gate electrode 32.

Shielding layer 227 is an example of a p-type fourth nitride semiconductor layer, and is provided between shielding electrode 238 and electron supply layer 124. Shielding layer 227 overlaps bottom surface 20a and side surface 20b of first opening 20 in plan view of substrate 10. Shielding layer 227 is provided between the upper surface of electron supply layer 124 and the lower surface of shielding electrode 238 in contact with each of them. Shielding layer 227 is electrically connected to shielding electrode 238.

Threshold adjustment layer 228 is an example of a p-type third nitride semiconductor layer, and is provided between gate electrode 232 and electron supply layer 124. Threshold adjustment layer 228 is provided between source electrode 34 and shielding layer 227 to be separated from each of source electrode 34 and shielding layer 227. Threshold adjustment layer 228 is electrically separated from both source electrode 34 and shielding layer 227. Threshold adjustment layer 228 is electrically connected to gate electrode 232.

In the present exemplary embodiment, threshold adjustment layer 228 is provided so as to contact and cover at least a part of the bottom surface of recess 126. Specifically, threshold adjustment layer 228 is provided so as to cover a bottom surface and a side surface of recess 126 and a portion outside recess 126. That is, the length of threshold adjustment layer 228 in the gate length direction is longer than the length of recess 126 in the gate length direction.

In addition, in the present exemplary embodiment, the first position is a position overlapping an end portion of threshold adjustment layer 228 on source electrode 34 side in plan view of substrate 10. When threshold adjustment layer 228 is not provided, the first position can be regarded as the position of the upper end of the sidewall of recess 126 on the side of source electrode 34. The second position overlaps shielding layer 227 in plan view of substrate 10. Specifically, the second position can be regarded as a position farthest from source electrode 34 in the flat portion of the upper surface of electron transit layer 22 in the gate length direction, that is, the position of the end portion of upper stage portion 124C of electron supply layer 124.

Shielding layer 227 and threshold adjustment layer 228 are formed by removing and separating a part of the nitride semiconductor film formed in the same step. Therefore, shielding layer 227 and threshold adjustment layer 228 have the same composition, thickness, carrier concentration, and the like. For example, each of shielding layer 227 and threshold adjustment layer 228 is a film containing, as a main component, p-type GaN having a thickness of 200 nm and a carrier concentration of 5×10¹⁷ cm⁻³.

Gate electrode 232 is provided above threshold adjustment layer 228. Gate electrode 232 is provided at a position overlapping block layer 14 without overlapping first opening 20 in plan view of substrate 10. Specifically, gate electrode 232 is provided in contact with the upper surface of threshold adjustment layer 228.

Shielding electrode 238 is provided above shielding layer 227 at a position overlapping first opening 20 in plan view of substrate 10. Shielding electrode 238 is electrically connected to source electrode 34 and shielding layer 227. Specifically, a source wiring (not illustrated) is connected to shielding electrode 238, and is set to the same potential as source electrode 34.

Gate electrode 232 and shielding electrode 238 are formed by removing and separating a part of the conductive film formed in the same step. Therefore, the main components of gate electrode 232 and shielding electrode 238 are the same. For example, each of gate electrode 232 and shielding electrode 238 contains, as a main component, a material that is ohmic-connected to a p-type nitride semiconductor such as p-type GaN. For example, Pd, a Ni-based material, WSi, Au, or the like can be used as a material for forming gate electrode 232 and shielding electrode 238.

According to nitride semiconductor device 201 of the present exemplary embodiment, the threshold of the transistor is determined by the flat portion of the channel outside first opening 20, and is not affected by the inclined portion of the channel. Therefore, controllability of on and off of the transistor can be enhanced. In addition, by providing shielding electrode 238 electrically connected to source electrode 34, shielding electrode 238 can terminate the line of electric force extending from drain electrode 36. Parasitic capacitance Cgd between the gate and the drain can be reduced, and the switching speed can be increased.

In addition, a source potential is supplied from shielding electrode 238 to shielding layer 227. Therefore, a reverse bias can be applied to the pn junction of shielding layer 227 and 2DEG 23 via shielding electrode 238 and drain electrode 36. Thus, the withstand voltage of nitride semiconductor device 201 can be increased.

Note that nitride semiconductor device 201 according to the present exemplary embodiment may include electron supply layer 24 according to the first exemplary embodiment instead of electron supply layer 124. That is, recess 126 may not be provided.

### FOURTH EXEMPLARY EMBODIMENT

Then, a fourth exemplary embodiment will be described.

The fourth exemplary embodiment is different from the first exemplary embodiment in the cross-sectional shape of the electron supply layer. Hereinafter, differences from the first exemplary embodiment will be mainly described, and description of common points will be omitted or simplified.

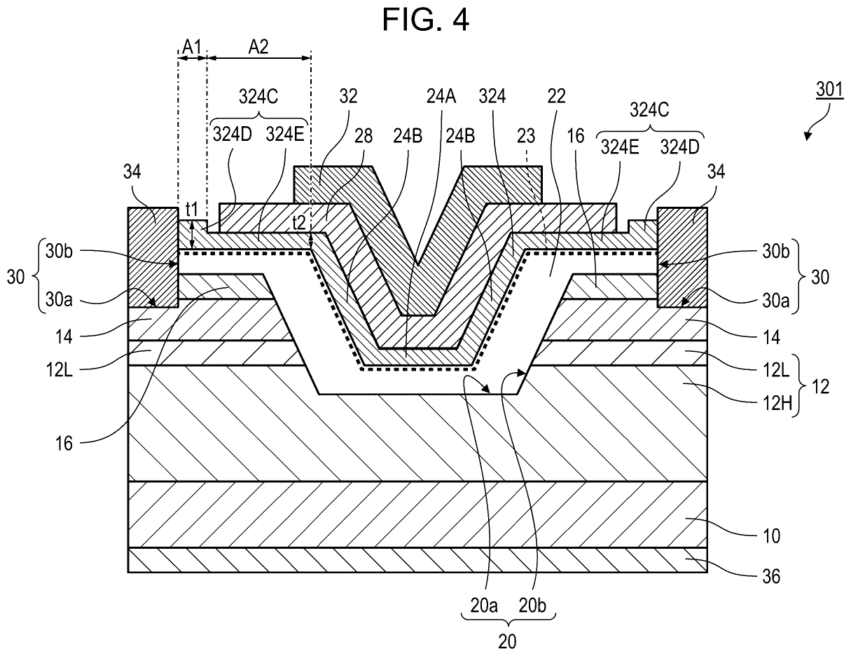

FIG. 4 is a cross-sectional view of nitride semiconductor device 301 according to the present exemplary embodiment. Nitride semiconductor device 301 illustrated in FIG. 4 includes electron supply layer 324 instead of electron supply layer 24 as compared with nitride semiconductor device 1 illustrated in FIG. 1.

Electron supply layer 324 has the same configuration as electron supply layer 24, but has a different cross-sectional shape. Specifically, electron supply layer 324 includes upper stage portion 324C instead of upper stage portion 24C of electron supply layer 24. Upper stage portion 324C includes thick film portion 324D and thin film portion 324E.

Thick film portion 324D is a portion of electron supply layer 324 that exists within first range A1 including the first position where the thickness becomes t1. The thickness of thick film portion 324D is constant at t1. Specifically, both the upper surface and the lower surface of thick film portion 324D are parallel to the main surface of substrate 10. In the present exemplary embodiment, thick film portion 324D is in contact with source electrode 34, but not in contact with threshold adjustment layer 28. A boundary between thick film portion 324D and thin film portion 324E is located between source electrode 34 and threshold adjustment layer 28. The first position is located between source electrode 34 and threshold adjustment layer 28 in plan view of substrate 10. For example, specifically, the first position can be regarded as a midpoint of the distance between threshold adjustment layer 28 and source electrode 34 in the gate length direction.

Thin film portion 324E is a portion of electron supply layer 324 that exists within second range A2 including the second position where the thickness becomes t2. The thickness of thin film portion 324E is constant at t2 and smaller than t1. Specifically, both the upper surface and the lower surface of thin film portion 324E are parallel to the main surface of substrate 10. There is a step between the upper surface of thin film portion 324E and the upper surface of thick film portion 324D. Second range A2 is a range closer to first opening 20 than first range A1 is in plan view of substrate 10. That is, thin film portion 324E is located at a position closer to first opening 20 than thick film portion 324D is in plan view. In plan view, a part of thin film portion 324E overlaps side surface 20b of first opening 20. At least a part of the upper surface of thin film portion 324E is covered with threshold adjustment layer 28.

As described above, in nitride semiconductor device 301 according to the present exemplary embodiment, since the thickness of upper stage portion 324C of electron supply layer 324 can be changed in a stepwise manner, each of a region having a high carrier concentration and a region having a low carrier concentration can be largely secured. Therefore, it is possible to effectively achieve both the reduction in the on-resistance and the improvement in the off-characteristics. The thickness of upper stage portion 324C may be changed in three or more stages.

Electron supply layer 324 including thick film portion 324D and thin film portion 324E can be formed by forming a nitride semiconductor film to be a base of electron supply layer 324 by crystal growth such as epitaxial growth and then removing a part thereof by etching.

Note that thick film portion 324D and thin film portion 324E are continuous, and a step is formed at the boundary between thick film portion 324D and thin film portion 324E on the upper surface of electron supply layer 324, but the present invention is not limited thereto. A transition portion in which the thickness of electron supply layer 324 gradually changes may be provided between thick film portion 324D and thin film portion 324E. That is, an inclination may be formed on the upper surface of electron supply layer 324.

### FIFTH EXEMPLARY EMBODIMENT

Then, a fifth exemplary embodiment will be described.

The fifth exemplary embodiment is mainly different from the fourth exemplary embodiment in that a recess is provided in the electron supply layer. Hereinafter, differences from the fourth exemplary embodiment will be mainly described, and description of common points will be omitted or simplified.

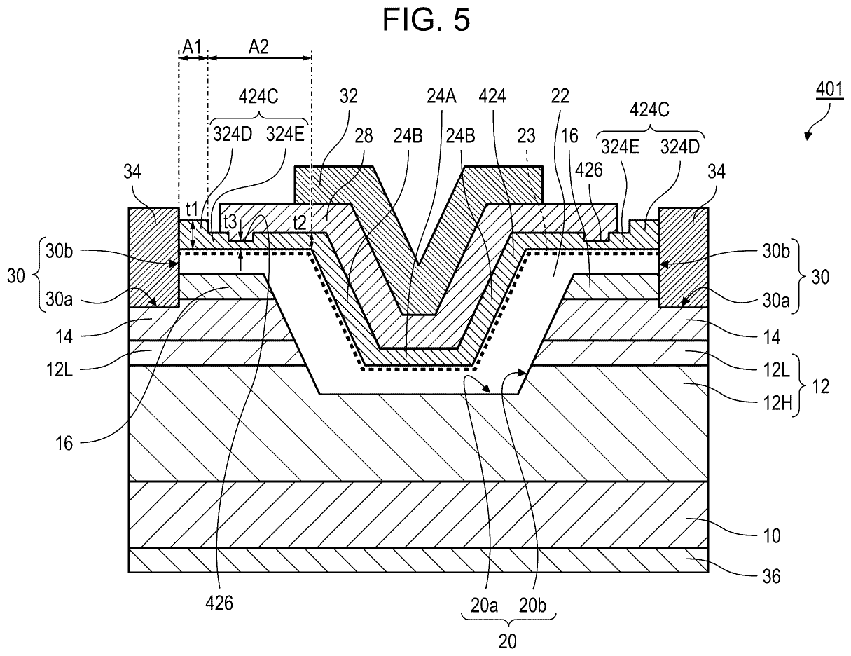

FIG. 5 is a cross-sectional view of nitride semiconductor device 401 according to the present exemplary embodiment. Nitride semiconductor device 401 illustrated in FIG. 5 includes electron supply layer 424 instead of electron supply layer 324 as compared with nitride semiconductor device 301 illustrated in FIG. 4.

Recess 426 is provided in upper stage portion 424C of electron supply layer 424. Upper stage portion 424C has the same configuration as upper stage portion 324C, except that recess 426 is provided. Recess 426 is provided on both left and right sides of first opening 20.

Recess 426 is provided within second range A2 at a position overlapping block layer 14 in plan view of substrate 10. Part or all of recess 426 may overlap side surface 20b of first opening 20 in plan view of substrate 10. Recess 426 is a recess recessed from the upper surface of electron supply layer 424 toward substrate 10. A side surface of recess 426 is perpendicular to the main surface of substrate 10, but may be inclined obliquely.

Threshold adjustment layer 28 is provided so as to cover recess 426. In a portion where recess 426 is provided, the thickness of electron supply layer 424 becomes small. As illustrated in FIG. 5, thickness t3 of a portion of electron supply layer 424 where recess 426 is provided is smaller than both thickness t1 at the first position and thickness t2 at the second position. That is, the relationship of t3<t2<t1 is satisfied.

As thickness t3 decreases, the concentration of 2DEG 23 in the direction immediately below recess 426 decreases. Therefore, the threshold of the transistor can be increased. For example, the threshold can be made higher than 0 V, which facilitates normally-off of the transistor. By adjusting the magnitude of thickness t3, the threshold of the transistor can be determined. For example, thickness t3 is between 10 nm and 60 nm (inclusive), for example, 20 nm.

In addition, a portion of upper stage portion 424C of electron supply layer 424 where recess 426 is not provided can be thickened without affecting the threshold of the transistor. That is, both thickness t1 at the first position and thickness t2 at the second position can be made large. For example, thicknesses t1 and t2 are between 10 nm and 70 nm (inclusive). As an example, thickness t1 is 65 nm and thickness t2 is 60 nm. By thickening the portion where recess 426 is not provided, the concentration of 2DEG 23 increases, so that the on-resistance can be reduced. By providing recess 426 in this manner, it is possible to achieve both the normally-off and the reduction in the on-resistance.

Recess 426 is formed by removing a part of electron supply layer 424 after forming electron supply layer 424 and before forming threshold adjustment layer 28. Electron supply layer 424 is removed by etching.

### SIXTH EXEMPLARY EMBODIMENT

Then, a sixth exemplary embodiment will be described.

The sixth exemplary embodiment is different from the fifth exemplary embodiment mainly in that a gate electrode is provided at a position not overlapping the first opening in plan view and a shielding electrode is provided at a position overlapping the first opening. Hereinafter, differences from the fifth exemplary embodiment will be mainly described, and description of common points will be omitted or simplified.

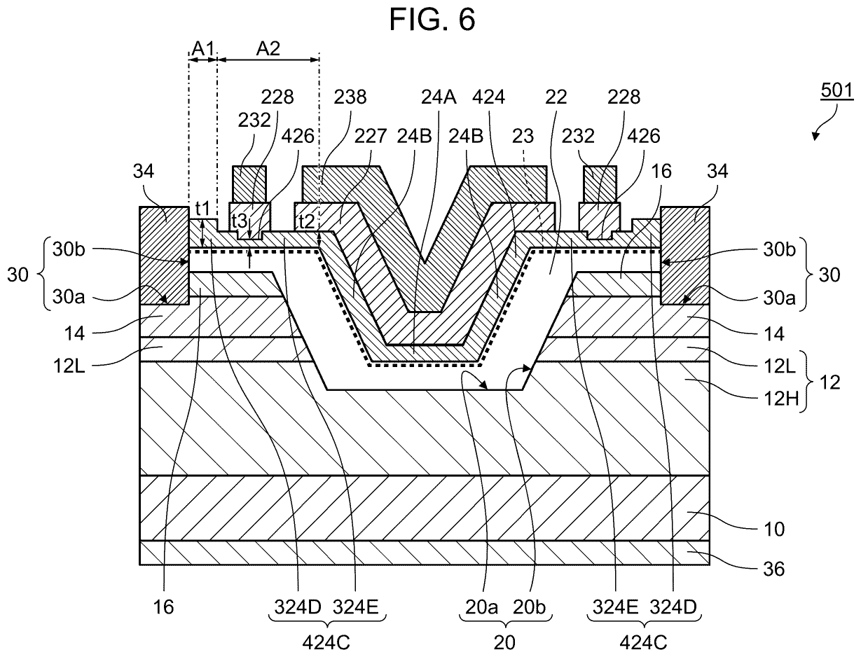

FIG. 6 is a cross-sectional view of nitride semiconductor device 501 according to the present exemplary embodiment. As compared with nitride semiconductor device 401 shown in FIG. 5, nitride semiconductor device 501 shown in FIG. 6 includes shielding layer 227, threshold adjustment layer 228, gate electrode 232, and shielding electrode 238 instead of threshold adjustment layer 28 and gate electrode 32.

Shielding layer 227, threshold adjustment layer 228, gate electrode 232, and shielding electrode 238 all have the same configurations as shielding layer 227, threshold adjustment layer 228, gate electrode 232, and shielding electrode 238 included in nitride semiconductor device 201 according to the third exemplary embodiment. Therefore, in nitride semiconductor device 501 according to the present exemplary embodiment, as in the third exemplary embodiment, shielding electrode 238 can terminate the lines of electric force extending from drain electrode 36. Parasitic capacitance Cgd between the gate and the drain can be reduced, and the switching speed can be increased. Similarly to the fifth exemplary embodiment, recess 426 is provided, so that both the normally-off and the reduction in on-resistance can be achieved.

Note that nitride semiconductor device 501 according to the present exemplary embodiment may include electron supply layer 324 according to the fourth exemplary embodiment instead of electron supply layer 424. That is, recess 426 may not be provided.

### SEVENTH EXEMPLARY EMBODIMENT

Then, a seventh exemplary embodiment will be described.

The seventh exemplary embodiment is different from the first exemplary embodiment in that the thickness of the bottom portion of the electron supply layer is small. Hereinafter, differences from the first exemplary embodiment will be mainly described, and description of common points will be omitted or simplified.

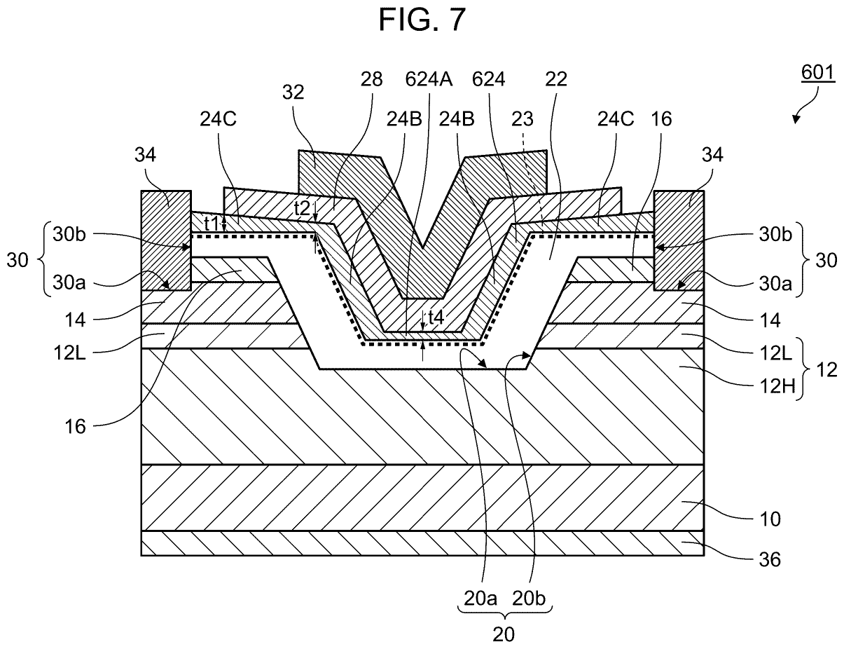

FIG. 7 is a cross-sectional view of nitride semiconductor device 601 according to the present exemplary embodiment. Nitride semiconductor device 601 illustrated in FIG. 7 includes electron supply layer 624 instead of electron supply layer 24 as compared with nitride semiconductor device 1 illustrated in FIG. 1.

Electron supply layer 624 has the same configuration as electron supply layer 24, but has a different cross-sectional shape. Specifically, electron supply layer 624 includes bottom portion 624A instead of bottom portion 24A of electron supply layer 24.

Similarly to bottom portion 24A, bottom portion 624A is a portion overlapping bottom surface 20a of first opening 20 in plan view of substrate 10, and is a portion having a substantially uniform thickness. The upper surface and the lower surface of bottom portion 624A are parallel to each other and parallel to the main surface of substrate 10.

Bottom portion 624A includes a third position where the thickness is t4. The third position is a position overlapping bottom surface 20a of first opening 20 in plan view of substrate 10. For example, the third position can be regarded as a position overlapping a midpoint of bottom surface 20a in the gate length direction. Thickness t4 is smaller than thickness t2 at the second position of electron supply layer 624. That is, in the present exemplary embodiment, t4<t2<t1 is satisfied.

By reducing thickness t4 of bottom portion 624A, the carrier concentration of 2DEG 23 in the vicinity of the bottom surface of first opening 20 can be reduced. As a result, the off-characteristics of nitride semiconductor device 601 can be further improved.

Note that thin bottom portion 624A may be provided in nitride semiconductor devices 101, 201, 301, 401, and 501 according to the second to sixth exemplary embodiments.

### OTHER EXEMPLARY EMBODIMENTS

The nitride semiconductor device according to one or more aspects has been described above based on the exemplary embodiments, but the present disclosure is not limited to these exemplary embodiments. Configurations in which various modifications conceivable by those skilled in the art are applied to the present exemplary embodiment and configurations constructed by combining components in different exemplary embodiments are also included in the scope of the present disclosure without departing from the gist of the present disclosure.

For example, second opening 30 may not be provided. In this case, source electrode 34 is provided on the upper surface of electron supply layer 24, 124, 324, 424, or 624, and is electrically connected to 2DEG 23 via electron supply layer 24.

In addition, for example, in nitride semiconductor devices 1, 101, 201, 301, 401, 501, and 601 according to the respective exemplary embodiments, a high-resistance layer having a resistance higher than that of block layer 14 may be provided between drift layer 12 and block layer 14. The high-resistance layer is, for example, a nitride semiconductor layer containing carbon-doped GaN (C—GaN) as a main component. The carbon concentration of the high-resistance layer is, for example, 3×10¹⁷ cm⁻³ or more, but may be 1×10¹⁸ cm⁻³ or more. The high-resistance layer is provided in contact with each of drift layer 12 and block layer 14. The high-resistance layer may contain n-type impurities such as Si. The concentration of the n-type impurity contained in the high-resistance layer is lower than the carbon concentration and the oxygen concentration of the high-resistance layer, and may be, for example, 5×10¹⁶ cm⁻³ or less, or 2×10¹⁶ cm⁻³ or less. By providing the high-resistance layer, punch-through can be suppressed, and the withstand voltage can be increased. When the high-resistance layer is formed, first opening 20 penetrates the high-resistance layer. As a result, since the high-resistance layer is not located on the path of the drain current at the time of ON, an increase in the on-resistance can be suppressed.

For example, threshold adjustment layer 28 or 228 may cover only a part of the bottom surface of recess 126 or 426 in contact with the bottom surface. That is, the bottom surface of recess 126 or 426 may be provided with a portion covered with an insulating film (not illustrated) or the like without being covered with threshold adjustment layer 28 or 228. For example, an end portion of threshold adjustment layer 28 or 228 on the side of source electrode 34 may be located on the bottom surface of recess 126 or 426. In this case, 2DEG 23 is not generated in the off state in the direction immediately below the bottom surface of recess 126 or 426 located closer to source electrode 34 than threshold adjustment layer 28. Therefore, since the area in which threshold adjustment layer 28 or 228 electrically connected to gate electrode 32 and 2DEG 23 face each other is reduced, gate-source capacitance Cgs can be reduced. When a portion that is not covered with threshold adjustment layer 28 or 228 exists on the bottom surface of recess 126 or 426, the first position can be regarded as the position of the upper end of the sidewall of recess 126 or 426 on the side of first opening 20 in plan view of substrate 10.

Not only the end portion of threshold adjustment layer 228 on the side of source electrode 34 but also the end portion on the opposite side thereof may be located on the bottom surface of recess 126 or 426. That is, threshold adjustment layer 228 may be provided so as not to contact a side surface of recess 126 or 426. Also in this case, since the area in which threshold adjustment layer 228 and 2DEG 23 face each other is reduced, gate-source capacitance Cgs can be reduced.

A side surface of recess 126 or 426 on the side of source electrode 34 may not be provided, and a bottom surface of recess 126 or 426 may extend immediately below source electrode 34. That is, part of source electrode 34 may contact and cover part of the bottom surface of recess 126 or 426.

In addition, various changes, replacements, additions, omissions, and the like can be made in each of the above exemplary embodiments within the scope of claims or equivalents thereof.

According to the present disclosure, it is possible to achieve both reduction in on-resistance and improvement in off-characteristics.

The nitride semiconductor device according to the present disclosure is useful as, for example, a power device used in a power supply circuit, an inverter circuit, or the like of an electric device.

What is claimed is:

1. A nitride semiconductor device, comprising:
a substrate;
a first nitride semiconductor layer of a first conductivity type disposed above the substrate;
a second nitride semiconductor layer of a second conductivity type disposed above the first nitride semiconductor layer, the second conductivity type being a polarity opposite to the first conductivity type; and
an electron transit layer and an electron supply layer disposed in order from the substrate side, and covering an inner surface of a first opening penetrating the second nitride semiconductor layer and reaching the first nitride semiconductor layer and above the second nitride semiconductor layer, wherein
a thickness of the electron supply layer at a first position is larger than a thickness of the electron supply layer at a second position, and
the second position is a position closer to the first opening than the first position is in plan view of the substrate.

2. The nitride semiconductor device according to claim 1, wherein a thickness of the electron supply layer gradually decreases from the first position toward the second position.

3. The nitride semiconductor device according to claim 2, wherein the electron supply layer is disposed with a recess between the first position and the second position at a position overlapping the second nitride semiconductor layer in plan view of the substrate.

4. The nitride semiconductor device according to claim 1, wherein
the thickness of the electron supply layer is constant in each of a first range including the first position and a second range including the second position, and
the second range is a range closer to the first opening than the first range is in plan view of the substrate.

5. The nitride semiconductor device according to claim 4, wherein the electron supply layer is disposed with a recess in the second range at a position overlapping the second nitride semiconductor layer in plan view of the substrate.

6. The nitride semiconductor device according to claim 1, wherein
a thickness of the electron supply layer at a third position is smaller than the thickness of the electron supply layer at the second position, and
the third position is a position overlapping a bottom surface of the first opening in plan view of the substrate.

7. The nitride semiconductor device according to claim 1, further comprising:
a gate electrode disposed above the electron supply layer;
a source electrode disposed above the substrate; and
a drain electrode disposed below the substrate.

8. The nitride semiconductor device according to claim 7, wherein the gate electrode is disposed at a position overlapping the first opening in plan view of the substrate.

9. The nitride semiconductor device according to claim 8, further comprising a third nitride semiconductor layer of the second conductivity type disposed between the gate electrode and the electron supply layer, wherein
the second position overlaps the third nitride semiconductor layer in plan view of the substrate, and
the first position is a position located between the third nitride semiconductor layer and the source electrode or overlapping an end portion of the third nitride semiconductor layer on the source electrode side in plan view of the substrate.

10. The nitride semiconductor device according to claim 7, further comprising a shielding electrode disposed at a position overlapping the first opening in plan view of the substrate and electrically connected to the source electrode, wherein
the gate electrode is disposed at a position overlapping the second nitride semiconductor layer without overlapping the first opening in plan view of the substrate.

11. The nitride semiconductor device according to claim 10, further comprising:
a third nitride semiconductor layer of the second conductivity type disposed between the gate electrode and the electron supply layer; and
a fourth nitride semiconductor layer of the second conductivity type disposed between the shielding electrode and the electron supply layer, wherein
the second position overlaps the fourth nitride semiconductor layer in plan view of the substrate, and
the first position is a position located between the third nitride semiconductor layer and the source electrode or overlapping an end portion of the third nitride semiconductor layer on the source electrode side in plan view of the substrate.
